(19) United States
(12) Patent Application Publication
(10) Pub. No.: US 2013/0340815 A1
(43) Pub. Date: Dec. 26, 2013

(54) ELECTRODE AND METHOD OF FORMING THE SAME AND ELECTRONIC DEVICE INCLUDING THE SAME

(71) Applicant: SAMSUNG ELECTRONICS CO., LTD., Suwon-si (KR)

(72) Inventors: Se-Yun KIM, Seoul (KR); Eun-Sung LEE, Hwaseong-si (KR); Suk-Jun KIM, Suwon-si (KR); Jin-Man PARK, Seoul (KR); Sang-Soo JEE, Hwaseong-si (KR); In-Yong SONG, Suwon-si (KR)

(73) Assignee: SAMSUNG ELECTRONICS CO., LTD., Suwon-si (KR)

(21) Appl. No.: 13/761,290

(22) Filed: Feb. 7, 2013

(30) Foreign Application Priority Data
Jun. 26, 2012 (KR) 10-2012-0068679

(51) Int. Cl. H01B 1/02; H01L 31/0224; C23C 28/02

(52) U.S. Cl. CPC H01B 1/02; C23C 28/027; H01L 31/022425
USPC 136/252; 428/553; 205/184

(57) ABSTRACT

An electrode including a first layer having a sintered product of a metallic glass and a first conductive material, and a second layer including a second conductive material plated using the first layer as a seed layer, a method of manufacturing the same, and an electronic device including the electrode.

### CROSS-REFERENCE TO RELATED APPLICATION

This application claims priority to and the benefit of Korean Patent Application No. 10-2012-0068679, filed in the Korean Intellectual Property Office on Jun. 26, 2012, and all the benefits accruing therefrom under 35 U.S.C. §119, the content of which is incorporated herein in its entirety by reference.

### BACKGROUND

1. Field

An electrode, a method of forming the same, and an electronic device including the electrode are disclosed.

2. Description of the Related Art

An electronic device such as a display device, a solar cell, and the like includes an electrode. The electrode may be fabricated by a deposition method, but this method is complicated, expensive, and time consuming. In order to simplify the process, it has been suggested to form a conductive paste including a conductive material using a screen printing method.

The conductive paste includes a conductive powder such as silver (Ag) and a glass frit. However, use of an expensive metal such as silver (Ag) causes a cost increase, and the glass frit is limited in increasing conductivity due to high resistivity. Thus, there remains a need for a cost effective electrode with improved conductivity.

An embodiment provides an electrode capable of saving cost and improving conductivity.

Another embodiment provides a method of forming the electrode.

Yet another embodiment provides an electronic device including the electrode.

According to an embodiment, an electrode is provided that includes a first layer including a sintered product of a metallic glass and a first conductive material, and a second layer including a second conductive material plated using the first layer as a seed layer.

The first conductive material may include a metal having resistivity of less than about 15 microohm×centimeter (“μΩcm”).

The first conductive material may include silver (Ag), aluminum (Al), copper (Cu), nickel (Ni), titanium (Ti), an alloy thereof, or a combination thereof.

The second conductive material may include a metal having resistivity of less than about 100 μΩcm.

The second conductive material may include copper (Cu), nickel (Ni), tin (Sn), titanium (Ti), aluminum (Al), an alloy thereof, or a combination thereof.

The first conductive material may include silver (Ag) or a silver alloy, and the second conductive material may include copper (Cu) or a copper alloy.

The metallic glass may have a glass transition temperature of about 50° C. to about 800° C.

The metallic glass may include an aluminum (Al)-based metallic glass, a copper (Cu)-based metallic glass, a nickel (Ni)-based metallic glass, a titanium (Ti)-based metallic glass, a tin (Sn)-based metallic glass, a cerium (Ce)-based metallic glass, a strontium (Sr)-based metallic glass, a gold (Au)-based metallic glass, a ytterbium (Yb)-based metallic glass, a zinc (Zn)-based metallic glass, a calcium (Ca)-based metallic glass, a magnesium (Mg)-based metallic glass, a platinum (Pt)-based metallic glass, a zirconium (Zr)-based metallic glass, an iron (Fe)-based metallic glass, or a combination thereof.

The second layer may be thicker than the first layer.

The first layer may have a thickness of about 0.1 micrometers (“μm”) to about 50 μm, and the second layer may have a thickness of about 0.2 μm to about 100 μm.

According to another embodiment, a method of manufacturing an electrode may include

applying a conductive paste including a first conductive material and a metallic glass on a substrate to provide a first layer, and

plating a second conductive material using the first layer as a seed layer to provide a second layer.

The providing a first layer may include printing a conductive paste on a substrate and firing the conductive paste.

The plating of a second conductive material includes wet plating using a plating solution.

The plating solution may be a basic plating solution.

The plating solution may be an acidic plating solution.

The method of manufacturing an electrode may further include providing a buffer layer on the substrate before providing the first layer.

According to yet another embodiment, an electronic device including the electrode is provided.

The electronic device may further include a buffer layer disposed between the first layer and a substrate.

The buffer layer may include polyimide.

The electronic device may be a solar cell.

### BRIEF DESCRIPTION OF THE DRAWINGS

These and/or other aspects of the present disclosure will become apparent and more readily appreciated from the following description of the embodiments, taken in conjunction with the accompanying drawings in which:

FIG. 1 is a cross-sectional view of an electrode according to an embodiment;

FIG. 2 is a cross-sectional view of a solar cell according to an embodiment;

FIG. 3 is a cross-sectional view of a solar cell according to another embodiment;

FIG. 4 is a scanning electron microscopy (“SEM”) photograph of an electrode sample according to Example 1;

FIG. 5 is a photograph enlarging the A part shown in FIG. 4;

FIG. 6 is a scanning electron microscopy (“SEM”) photograph of an electrode sample according to Example 2; and

FIG. 7 and FIG. 8 are, respectively, photographs of sections B and C shown in FIG. 6.

### DETAILED DESCRIPTION

Exemplary embodiments will hereinafter be described in further detail with reference to the accompanying drawings, in which various embodiments are shown. This disclosure may, however, be embodied in many different forms and should not be construed as limited to the exemplary embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

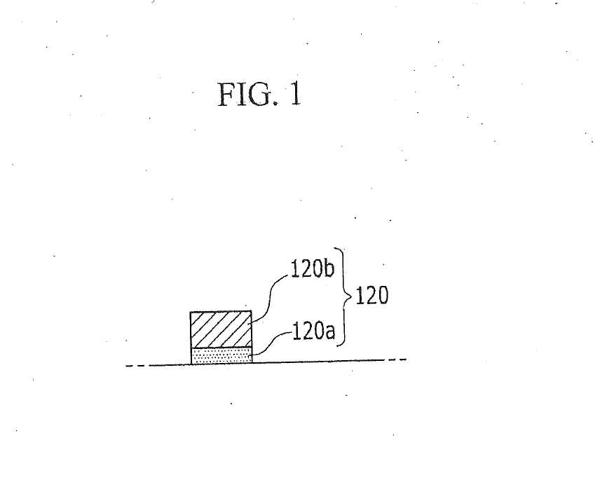

Hereinafter, an electrode according to an embodiment is described referring to FIG. 1.

FIG. 1 is a schematic view of an electrode according to an embodiment.

The electrode 120 according to an embodiment includes a first layer 120a and a second layer 120b plated using the first layer 120a as a seed layer.

The first layer 120a includes a sintered product of a metallic glass and a first conductive material.

The first conductive material may be a low resistance metal having resistivity of less than about 15 microohm×centimeter (“μΩcm”), for example a silver (Ag)-containing metal such as silver or a silver alloy, an aluminum (Al)-containing metal such as aluminum or an aluminum alloy, a copper (Cu)-containing metal such as copper (Cu) or a copper alloy, a nickel (Ni)-containing metal such as nickel (Ni) or a nickel alloy, a titanium (Ti)-containing metal such as titanium (Ti) or a titanium alloy, or a combination thereof.

The metallic glass includes an alloy having a disordered atomic structure including two or more metals or semi-metals. The metallic glass may include an amorphous metal. The metallic glass includes an amorphous part that is formed by rapidly solidifying a plurality of metals or semi-metals. Accordingly, the metallic glass is different from the general alloy having a crystalline structure in which atoms are regularly arranged when solidified and from liquid metals present in a liquid phase at room temperature.

Herein, the amorphous part may be about 50 percent by weight (“wt %”) to about 100 wt % of the metallic glass, specifically, about 70 wt % to about 100 wt %, and more specifically, about 90 wt % to about 100 wt %. The metallic glass has low resistivity and thus high conductivity, unlike a glass such as a silicate.

The metallic glass is softened at more than or equal to a glass transition temperature (“Tg”), and may act like a liquid at that temperature. This liquid-like behavior is maintained between the glass transition temperature (“Tg”) and the crystalline temperature (“Tₓ”) of metallic glass, which is called a supercooled liquid region (“ΔT_{X}”).

While the metallic glass acts like a liquid, its wettability may widen the contact area between a conductive paste and the lower layer (such as a substrate). Accordingly, the electron tunneling channels are formed between the electrode from the conductive paste and the lower layer, thereby enhancing the electrical conductivity of the electrode.

The metallic glass may have a glass transition temperature (“Tg”) of about 50° C. to about 800° C. The metallic glass may include, for example, an aluminum (Al)-based metallic glass, a copper (Cu)-based metallic glass, a nickel (Ni)-based metallic glass, a titanium (Ti)-based metallic glass, a tin (Sn)-based metallic glass, a cerium (Ce)-based metallic glass, a strontium (Sr)-based metallic glass, a gold (Au)-based metallic glass, an ytterbium (Yb)-based metallic glass, a zinc (Zn)-based metallic glass, a calcium (Ca)-based metallic glass, a magnesium (Mg)-based metallic glass, a platinum (Pt)-based metallic glass, a zirconium (Zr)-based metallic glass, an iron (Fe)-based metallic glass, or a combination thereof, but is not limited thereto.

Each of the aluminum (Al)-based metallic glass, copper (Cu)-based metallic glass, nickel (Ni)-based metallic glass, titanium (Ti)-based metallic glass, tin (Sn)-based metallic glass, cerium (Ce)-based metallic glass, strontium (Sr)-based metallic glass, gold (Au)-based metallic glass, ytterbium (Yb)-based metallic glass, zinc (Zn)-based metallic glass, calcium (Ca)-based metallic glass, magnesium (Mg)-based metallic glass, platinum (Pt)-based metallic glass, zirconium (Zr)-based metallic glass, and iron (Fe)-based metallic glass may be an alloy including aluminum, copper, nickel, titanium, tin, cerium, strontium, gold, ytterbium, zinc, calcium, magnesium, platinum, zirconium, or iron as a main component, respectively, and may further include, for example, nickel (Ni), yttrium (Y), cobalt (Co), lanthanum (La), zirconium (Zr), iron (Fe), titanium (Ti), calcium (Ca), beryllium (Be), magnesium (Mg), sodium (Na), molybdenum (Mo), tungsten (W), tin (Sn), zinc (Zn), potassium (K), lithium (Li), phosphorus (P), palladium (Pd), platinum (Pt), rubidium (Rb), chromium (Cr), strontium (Sr), cerium (Ce), praseodymium (Pr), promethium (Pm), samarium (Sm), lutetium (Lu), neodymium (Nd), niobium (Nb), gadolinium (Gd), terbium (Tb), dysprosium (Dy), holmium (Ho), erbium (Er), thulium (Tm), thorium (Th), scandium (Sc), barium (Ba), ytterbium (Yb), europium (Eu), hafnium (Hf), arsenic (As), plutonium (Pu), gallium (Ga), germanium (Ge), antimony (Sb), silicon (Si), cadmium (Cd), indium (In), manganese (Mn), niobium (Nb), osmium (Os), vanadium (V), aluminum (Al), copper (Cu), silver (Ag), mercury (Hg), or a combination thereof, but is not limited thereto. The main component of the metallic glass may be included in an amount of greater than or equal to about 50 mole percent (“mol %”) based on 100 mol % of the metallic glass.

The first conductive material and the metallic glass may be included in an amount of about 30 wt % to 99.9 wt % and about 0.01 wt % to about 70 wt %, respectively, based on the total amount of the first conductive material and the metallic glass.

The first electrode 120a may be formed by applying (printing) the conductive paste including the first conductive material and the metallic glass and firing the same. Thus, the first electrode 120a may adopt a shape of a sintered product of the metallic glass and the first conductive material.

The second electrode 120b is a plating layer including a second conductive material, wherein the second conductive material is plated using the first electrode 120a as a seed layer.

The second conductive material may be a relatively inexpensive metal, for example a less expensive metal than silver. The second conductive material may also have relatively low resistivity, for example, a resistivity of less than about 100 μΩcm. The second conductive material may be, for example a copper (Cu)-containing metal such as copper (Cu) or a copper alloy, a nickel (Ni)-containing metal such as nickel (Ni) or a nickel alloy, a tin (Sn)-containing metal such as tin (Sn) or a tin alloy, a titanium (Ti)-containing metal such as titanium (Ti) or a titanium alloy, an aluminum (Al)-containing metal such as aluminum (Al) or an aluminum alloy, or a combination thereof, but is not limited thereto. In an embodiment, the first conductive material may include silver (Ag) or a silver alloy, and the second conductive material may include copper (Cu) or a copper alloy.

On the other hand, an intermetallic compound may be formed between the metal of the first electrode 120a and the metal of the second electrode 120b when the second electrode 120b is electro-plated on the first electrode 120a. Such an intermetallic compound may improve the bonding properties between the first electrode 120a and the second electrode 120b. The intermetallic compound may be formed when the heat of mixing the two metals is less than 0. The intermetallic compound may also be formed with the second conductive material by including at least one component having a heat of mixing with the second conductive material of less than 0 in the metallic glass.

For example, when the first conductive material is silver (Ag) and the second conductive material is copper (Cu), the heat of mixing between silver the two metals is about +2, and it is therefore difficult to spontaneously form an intermetallic compound between them. On the other hand, the first electrode 120a may further include a metallic glass including a component having a heat of mixing with copper (Cu) of less than 0, excluding silver (Ag), for example, an aluminum-based metallic glass or the like. In this case, an intermetallic compound may be formed between the metal glass of the first electrode 120a and copper (Cu) of the second electrode 120b to improve the bonding property between the first electrode 120a and the second electrode 120b.

Thus, when the second conductive material is plated using the first electrode 120a including a first conductive material and a metallic glass as a seed layer, the bonding properties between the first electrode 120a and the second electrode 120b may be improved, compared to the case when the first electrode includes only the first conductive material as a seed layer.

The thickness of the electrode 120 may be about 0.5 μm to about 150 μm. When the electrode 120 has a thickness within the foregoing range, the cross-sectional area of the electrode is increased and the line resistance is reduced.

The second layer 120b may be thicker than the first layer 120a.

The first layer 120a may have a sufficient thickness to serve as a seed layer when plating the second layer 120b. Specifically, a thickness of the first layer may be about 0.1 μm to about 50 μm, specifically, about 1 μm to about 50 μm, more specifically, about 1 μm to about 30 μm.

The thickness of the second layer 120b may be about 0.2 μm to about 100 μm, specifically, about 1 μm to about 50 μm, more specifically, about 1 μm to about 30 μm.

When the first layer 120a and the second layer 120b have a thickness within the foregoing ranges, the line resistance decrease may be ensured and the manufacturing cost may be decreased by decreasing the amount of expensive metal.

Hereinafter, a method of manufacturing an electrode according to an embodiment is further described in accordance with FIG. 1.

The method of manufacturing an electrode according to an embodiment includes applying (e.g., printing) a conductive paste including a first conductive material and a metallic glass on a substrate (not shown) to provide a first layer 120a and plating a second conductive material using the first layer 120a as a seed layer to provide a second layer 120b.

The substrate may be, for example, a glass substrate, a silicon wafer, a polymer film, and the like.

The conductive paste may further include an organic vehicle in addition to the first conductive material and a metallic glass described above.

The first conductive material may be formed as a powder, for example, as a powder of particles having a size of about 1 nanometer (“nm”) to about 50 μm, specifically, about 100 nm to about 50 μm, more specifically, about 100 nm to about 30 μm. The particles can have a monomodal, bimodal, or higher distribution.

The metallic glass may also be included as a powder.

The organic vehicle may include an organic compound combined with the first conductive material and metallic glass that imparts a desired viscosity to the organic vehicle, and a solvent capable of dissolving the above components.

The organic compound may include, for example, a poly(meth)acrylate resin or a copolymer thereof, a cellulose resin such as ethyl cellulose, a phenol resin, an alcohol resin such as a 4-alkoxybenzyl alcohol resin, TEFLON (poly(tetrafluoroethylene)), or a combination thereof, but is not limited thereto. Alternatively, or in addition, the organic vehicle and may include an additive such as a dispersing agent, a surfactant, a thickener, and a stabilizer.

The solvent may be any solvent capable of dissolving the foregoing compounds, and may include, for example, terpineol, butylcarbitol, butylcarbitol acetate, pentanediol, dipentyne, limonene, ethylene glycol alkylether, diethylene glycol alkylether, ethylene glycol alkylether acetate, diethylene glycol alkylether acetate, diethylene glycol dialkylether acetate, triethylene glycol alkylether acetate, triethylene glycol alkylether, propylene glycol alkylether, propylene glycol phenylether, dipropylene glycol alkylether, tripropylene glycol alkylether, propylene glycol alkylether acetate, dipropylene glycol alkylether acetate, tripropylene glycol alkyl ether acetate, dimethylphthalic acid, diethylphthalic acid, dibutylphthalic acid, desalted water, or a combination thereof, but is not limited thereto. The forming of the first layer 120a may include applying (e.g., printing) the conductive paste on the substrate and firing the conductive paste.

The applying (e.g., printing) the conductive paste may be performed by a screen printing method, but is not limited thereto. It may be performed by a method such as inkjet printing or imprinting. The conductive paste may be applied to form a continuous or discontinuous layer.

The firing of the conductive paste may be performed at a temperature higher than the melting temperature of the conductive paste, for example, at about 200° C. to about 1,000° C., and specifically, about 500° C. to about 900° C.

The providing of the second layer 120b may include plating a second conductive material wherein the first layer 120a functions as a seed layer for the formation of the second layer. The plating process may be performed by a wet plating method using, for example, a plating solution. The plating solution may include, for example, a metal salt including the second conductive material in a form of ions, a reducing agent for reducing the ions of the second conductive material, and optionally an additive.

The plating solution may be a basic plating solution, for example, a metal pyrophosphate, or an acidic plating solution, for example, metal sulfate.

When the second layer 120b is formed using the acidic plating solution, the method may further include providing a buffer layer on the substrate before forming the first layer 120a. The buffer layer may prevent an oxide layer spontaneously formed in the air on the surface of the substrate such as a silicon wafer from being etched by the acidic plating solution, thus preventing delamination of the electrode 120 from the substrate.

The buffer layer may be made of, for example, polyimide, but is not limited thereto.

The second conductive material may be grown in a direction of thickness of the first layer 120a to provide the second layer 120b having a predetermined thickness.

The electrode 120 may be applied to various electronic devices. The electronic device may include, for example a liquid crystal display (“LCD”), a plasma display device (“PDP”), an organic light emitting diode (“OLED”) display, a solar cell, and the like, but is not limited thereto.

As an example of the electronic device, a solar cell is described herein referring to the drawings.

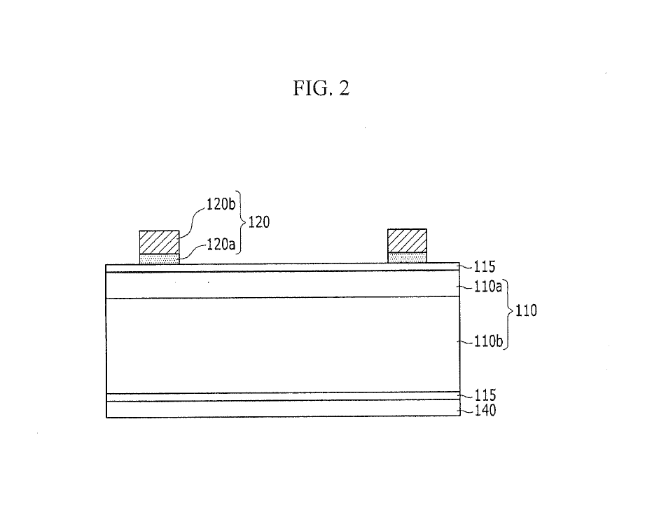

FIG. 2 is a cross-sectional view of a solar cell according to an embodiment.

Hereinafter, the spatial relationship of components will be described with respect to a semiconductor substrate 110 for better understanding and ease of description, but the present disclosure is not limited thereto. In addition, a solar energy incident side of a semiconductor substrate 110 is termed a front side, and the opposite side is called a rear side, although alternative configurations are possible.

Referring to FIG. 2, a solar cell according to an embodiment may include a semiconductor substrate 110 including a lower semiconductor layer 110a and an upper semiconductor layer 110b.

The semiconductor substrate 110 may include crystalline silicon or a compound semiconductor. The crystalline silicon may be, for example, a silicon wafer. Either of the lower semiconductor layer 110a and the upper semiconductor layer 110b may be a semiconductor layer doped with a p-type impurity, while the other may be a semiconductor layer doped with an n-type impurity. For example, the lower semiconductor layer 110a may be a semiconductor layer doped with a p-type impurity, and the upper semiconductor layer 110b may be a semiconductor layer doped with an n-type impurity. Herein, the p-type impurity may be a Group III element such as boron (B), and the n-type impurity may be a Group V element such as phosphorus (P).

A thin silicon oxide layer 115 may be formed on the semiconductor substrate 110. The silicon oxide layer 115 may be formed through natural oxidation of the semiconductor substrate 110. Alternatively a thin silicon oxide layer 115 may be absent.

A plurality of electrodes 120 may be formed on the silicon oxide layer 115. The electrodes 120 may be arranged in parallel to the substrate, and may form a grid pattern to reduce shadowing loss and sheet resistance.

Each electrode 120 includes a first layer 120a including a sintered product of a metallic glass and a first conductive material, and a second layer 120b plated with a second conductive material using the first layer 120a as a seed layer.

The electrode 120 may include a buffer part (not shown) disposed on an area adjacent to the upper semiconductor layer 110b, and an electrode part (not shown) disposed on an area other than the buffer part and including a conductive material.

The buffer part may be one layer formed by softening the metallic glass included in the conductive paste at greater than or equal to the glass transition temperature (“Tg”) during the process. Since the buffer part has conductivity due to the metallic glass, and the area of a path capable of transferring charges between the upper semiconductor layer 110b and the electrode part is widened by including a part contacting the electrode part and a part contacting the upper semiconductor layer 110b, charge loss is decreased. As a result, the conductivity of electrode may be improved.

A bus bar electrode (not shown) may be disposed on the electrode 120. The bus bar electrode may connect a plurality of adjacent solar cells.

The semiconductor substrate 110 is spontaneously oxidized to provide a silicon oxide layer 115 having a low thickness under the semiconductor substrate 110. However, the silicon oxide layer 115 may be absent.

An electrode 140 may be disposed under the silicon oxide layer 115. The electrode 140 may include a conductive material, for example, an opaque metal such as aluminum (Al). The electrode 140 is shown as a single layer, but is not limited thereto. It may be formed as a double layer like the electrode 120. The electrode 140 may be formed using a conductive paste according to the screen printing method, like the electrode 120.

Hereinafter, a method of manufacturing the solar cell of FIG. 2 is further described.

First, a semiconductor substrate 110, which may be a silicon wafer for example, is prepared. The semiconductor substrate 110 may be doped with a p-type impurity, for example.

Then, the semiconductor substrate 110 may be subjected to a surface-texturing treatment. The surface-texturing treatment may be performed by a wet method using a strong acid such as nitric acid or hydrofluoric acid, or a strong base such as sodium hydroxide, or by a dry method such as plasma treatment.

Then, the semiconductor substrate 110 may be doped with an n-type impurity, for example. The n-type impurity may be introduced by diffusing POCl₃, H₃PO₄, or the like at a high temperature. The semiconductor substrate 110 may include the lower semiconductor layer 110a and the upper semiconductor layer 110b doped with different impurities.

Then a conductive paste may be applied to the position where the electrode 120 is to be formed, i.e., on the front surface of semiconductor substrate 110, and dried according to a screen printing method. However, the printing is not limited to the screen printing method, and may be formed according to various printing methods such as inkjet printing, imprinting, or the like.

As discussed above, the conductive paste may include a metallic glass. The metallic glass may be prepared using any method known in the art, such as melt spinning, infiltration casting, gas atomization, ion irradiation, or mechanical alloying.

A conductive paste may be applied to the position where the electrode 140 is to be formed, i.e., on the rear surface of semiconductor substrate 110 and dried according to a screen printing method.

The semiconductor substrate 110 may be fired in a furnace at a high temperature. The firing may be performed at a temperature greater than the fusion temperature of the conductive paste, specifically, at a temperature of about 200° C. to about 1000° C., and more specifically, about 500° C. to about 900° C.

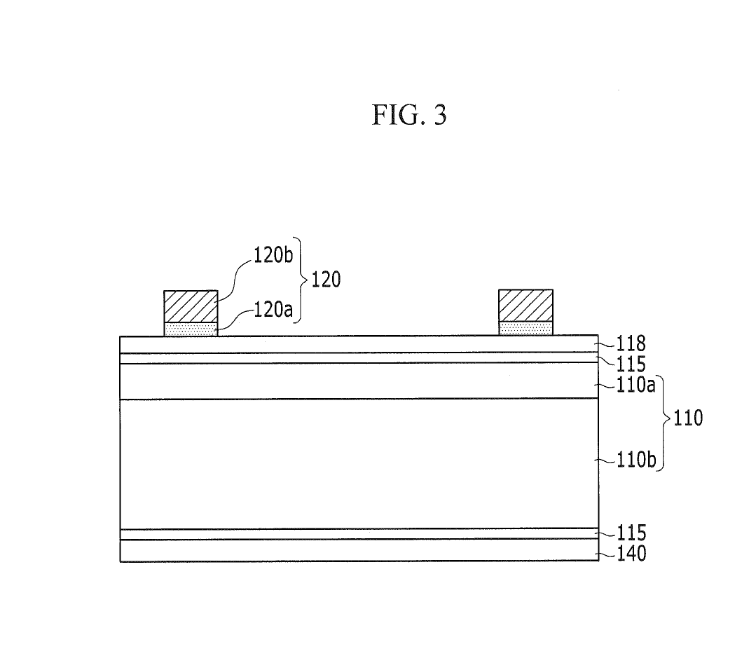

Hereinafter, the solar cell according to another embodiment is described with reference to FIG. 3.

FIG. 3 is a cross-sectional view of a solar cell according to another embodiment.

As shown in FIG. 3, the solar cell according to an embodiment includes a semiconductor substrate 110 including a lower semiconductor layer 110a and an upper semiconductor layer 110b, a silicon oxide layer 115, and electrodes 120 and 140, as described above with reference to FIG. 2.

However, the solar cell according to an embodiment may further include a buffer layer 118 positioned under the electrode 120, i.e., between the first layer of the electrode and the substrate, which in FIG. 3 further includes the silicon oxide layer 115. The buffer layer 118 may prevent a silicon oxide layer 115 from being etched when plating the electrode 120 using an acidic plating solution, so as to prevent the delamination of the electrode 120 from the semiconductor substrate 110. The buffer layer 118 may be made of polyimide, but is not limited thereto.

Hereinafter, the following examples illustrate the present disclosure in further detail. However, it should be understood that the present disclosure is not limited by these examples.

### Example 1

Silver (Ag) powder and metallic glass Al₈₅Ni₅Co₂Y₈ are added into an organic vehicle including an ethylcellulose binder, a surfactant, and a mixed solvent of butylcarbitol/butylcarbitol acetate. The silver (Ag) powder, metallic glass Al₈₅Ni₅Co₂Y₈, and organic vehicle are mixed at 82.58 wt %, 3.93 wt %, and 13.49 wt %, respectively, based on the total amount of the conductive paste. Then, the mixture is kneaded using a 3-roll mill to provide a conductive paste. The conductive paste is subsequently applied on the silicon wafer according to the screen printing method. Subsequently, the conductive paste is heated to about 600° C. using a belt furnace and cooled to provide a seed layer. A basic plating solution is prepared. The basic plating solution includes copper pyrophosphate, potassium pyrophosphate, copper nitrate trihydrate, ammonia, and poly(ethylene glycol) (Mw=3,350) in an amount of 30 gram per liter (“g/L”) of Cu²⁺, 200 g/L of pyrophosphate (P₂O₇⁴⁻), 7 g/L of nitrate (NO³⁻), and 2 g/L of ammonia (NH₃) are included in the basic plating solution. A silicon wafer formed with the seed layer is attached to one electrode, and a platinum (Pt) electrode is used as an opposed electrode. The silicon wafer and the platinum (Pt) electrode are immersed in the basic plating solution, and a constant current is flowed between two electrodes for 5 minutes to provide a Cu plating layer having a thickness of about 0.5 μm.

### Example 2

Silver (Ag) powder and metallic glass Al₈₅Ni₅Co₂Y₈ are added into an organic vehicle including an ethylcellulose binder, a surfactant, and a mixed solvent of butylcarbitol/butylcarbitol acetate. The silver (Ag) powder, metallic glass Al₈₅Ni₅Co₂Y₈, and organic vehicle are mixed at 82.58 wt %, 3.93 wt %, and 13.49 wt %, respectively, based on the total amount of the conductive paste. Then the mixture is kneaded using a 3-roll mill to provide a conductive paste. A polyamide solution is coated on a silicon wafer and heated at 350° C. to provide a polyimide layer (buffer layer) having a thickness of 0.5 μm to 5 μm. The conductive paste is subsequently coated on the polyimide layer according to a screen printing method. The conductive paste is then heated to about 600° C. in a belt furnace and cooled to provide a seed layer.

Then an acidic plating solution is prepared. The acidic plating solution includes 100 g/L of copper sulfate, 180 g/L of sulfuric acid, and 50 milligram per liter (“mg/L”) of chloride. The silicon wafer formed with the seed layer is attached to one electrode, and a platinum (Pt) electrode is used as an opposed electrode. The silicon wafer and the platinum (Pt) electrode are immersed in the acidic plating solution, and the constant current is flowed between two electrodes for 10 minutes to provide a Cu plating layer having a thickness of about 2 μm.

### Comparative Example 1

An electrode sample is manufactured in accordance with the same procedure as in Example 1, except for not forming the Cu plating layer.

### Comparative Example 2

An electrode sample is manufactured in accordance with the same procedure as in Example 2, except for not providing the Cu plating layer.

Evaluation 1

The electrode samples according to Examples 1 and 2 are observed using a scanning electron microscope (“SEM”).

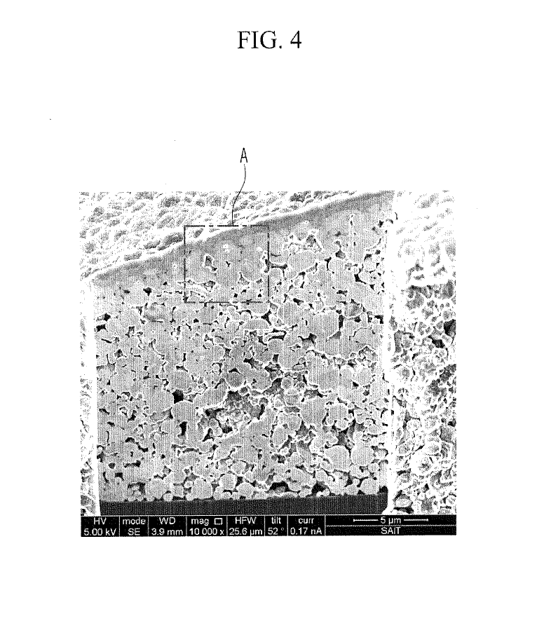

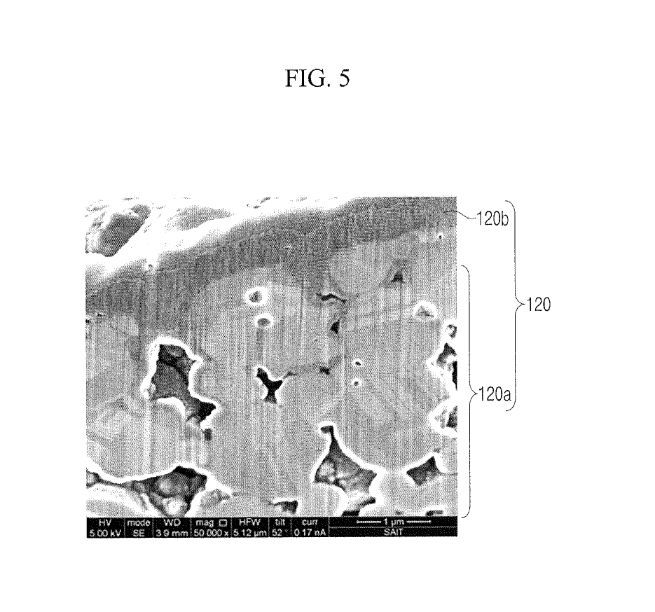

FIG. 4 is a scanning electron microscope (“SEM”) photograph of an electrode sample according to Example 1, and FIG. 5 is an enlarged reproduction of section A shown in FIG. 4.

Referring to FIG. 4 and FIG. 5, it is determined that the electrode sample according to Example 1 is formed with the first layer 120a made of a sintered product of silver (Ag) and a metallic glass and a second layer 120b plated with copper (Cu) thereon.

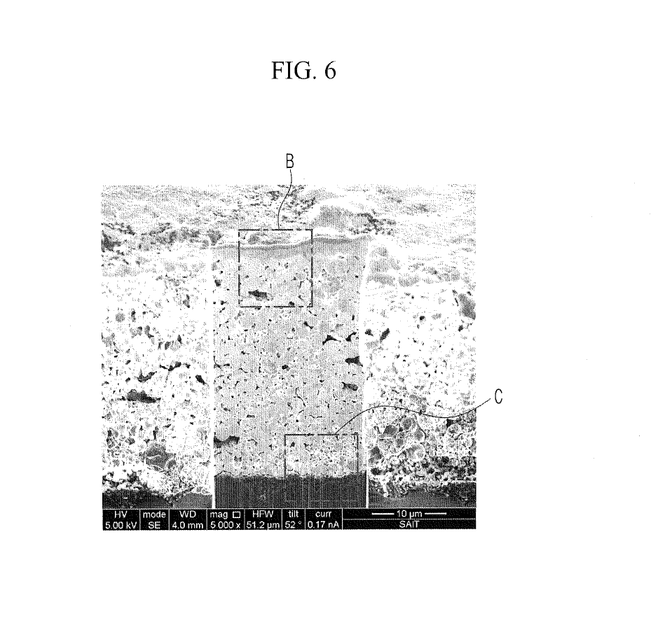

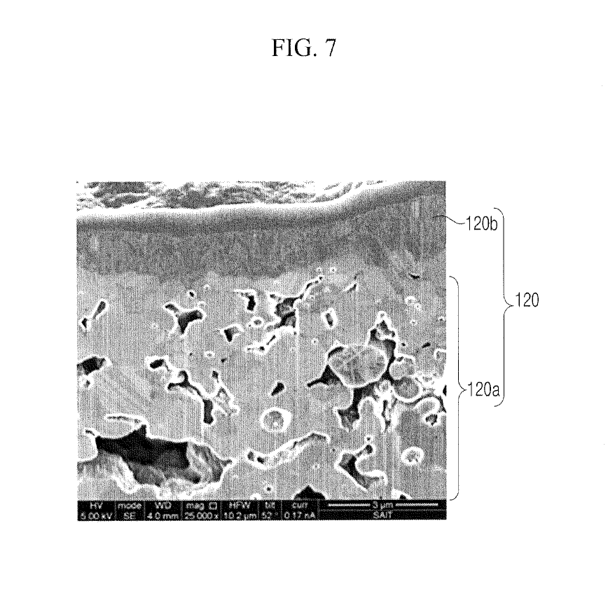

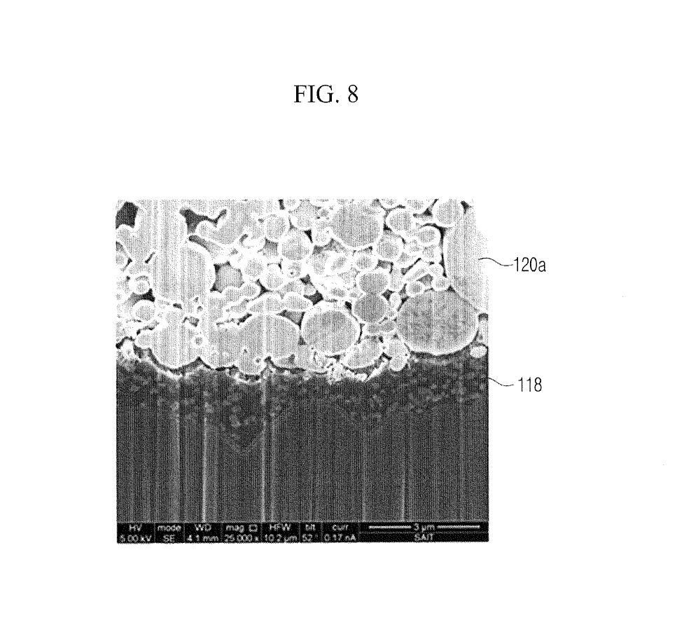

FIG. 6 is a scanning electron microscope (“SEM”) photograph of an electrode sample according to Example 2, and FIG. 7 and FIG. 8 are enlarged reproductions of sections B and C, respectively, shown in FIG. 6.

Referring to FIG. 6 to FIG. 8, it is determined that the electrode sample according to Example 2 is formed with the buffer layer 118 made of polyimide, the first layer 120a made of a sintered product of silver (Ag) and a metallic glass, and the second layer 120b plated with copper (Cu).

Evaluation 2

The electrode samples according to Examples 1 and 2 and Comparative Examples 1 and 2 are evaluated for conductivity. The conductivity is evaluated by line resistance, and the line resistance is measured using a 2-point probe. For example, an electrode having a predetermined length is prepared, and then probes are connected to both ends thereof and measured for resistance. Then the resistance value is divided by the length of the electrode to calculate the line resistance.

The results are shown in Table 1.

TABLE 1

| | Line resistance | | Line resistance |
|---|---|---|---|
| | (Ω/cm) | | (Ω/cm) |
| Example 1 | 0.105 | Example 2 | 0.127 |
| Comparative | 0.114 | Comparative | 0.149 |
| Example 1 | | Example 2 | |

Referring to Table 1, it is determined that the electrode sample according to Example 1 decreases the line resistance by about 8%, compared to the electrode sample according to Comparative Example 1, and the electrode sample according to Example 2 decreases the line resistance by about 14%, compared to the electrode sample according to Comparative Example 2.

While this disclosure has been described in connection with what is presently considered to be embodiments, it should be understood that the invention is not limited to the disclosed embodiments, but, on the contrary, is intended to cover various modifications and equivalent arrangements included within the spirit and scope of the appended claims.

What is claimed is:

1. An electrode comprising:
a first layer comprising a sintered product of a metallic glass and a first conductive material; and
a second layer comprising a second conductive material plated using the first layer as a seed layer.

2. The electrode of claim 1, wherein the first conductive material comprises a metal having resistivity of less than about 15 μΩcm.

3. The electrode of claim 2, wherein the first conductive material comprises silver, aluminum, copper, nickel, titanium, an alloy thereof, or a combination thereof.

4. The electrode of claim 1, wherein the second conductive material comprises a metal having resistivity of less than about 100 μΩcm.

5. The electrode of claim 4, wherein the second conductive material comprises copper, nickel, tin, titanium, aluminum, an alloy thereof, or a combination thereof.

6. The electrode of claim 1, wherein the first conductive material comprises silver or a silver alloy, and
the second conductive material comprises copper or a copper alloy.

7. The electrode of claim 1, wherein the metallic glass has a glass transition temperature of about 50° C. to about 800° C.

8. The electrode of claim 1, wherein the metallic glass comprises an aluminum-based metallic glass, a copper-based metallic glass, a nickel-based metallic glass, a titanium-based metallic glass, a tin-based metallic glass, a cerium-based metallic glass, a strontium-based metallic glass, a gold-based metallic glass, a ytterbium-based metallic glass, a zinc-based metallic glass, a calcium-based metallic glass, a magnesium-based metallic glass, a platinum-based metallic glass, a zirconium-based metallic glass, an iron-based metallic glass, or a combination thereof.

9. The electrode of claim 1, wherein the second layer is thicker than the first layer.

10. The electrode of claim 9, wherein the first layer has a thickness of about 0.1 micrometers to about 50 micrometers, and
the second layer has a thickness of about 0.2 micrometers to about 100 micrometers.

11. A method of manufacturing an electrode, comprising:
applying a conductive paste comprising a first conductive material and a metallic glass on a substrate to provide a first layer; and
plating a second conductive material using the first layer as a seed layer to provide a second layer.

12. A method of claim 11, wherein the providing a first layer comprises:
applying the conductive paste on the substrate; and
firing the conductive paste.

13. The method of claim 11, wherein the plating of a second conductive material comprises wet plating using a plating solution.

14. The method of claim 13, wherein the plating solution is a basic plating solution.

15. The method of claim 13, wherein the plating solution is an acidic plating solution.

16. The method of claim 15, further comprising providing a buffer layer on the substrate before providing a first layer.

17. An electronic device comprising the electrode according to claim 1.

18. The electronic device of claim 17, further comprising a buffer layer positioned between the first layer of the electrode and a substrate.

19. The electronic device of claim 18, wherein the buffer layer comprises polyimide.

20. The electronic device of claim 17, wherein the electronic device is a solar cell.
